(19) United States
(12) Patent Application Publication
(10) Pub. No.: US 2024/0096594 A1
(43) Pub. Date: Mar. 21, 2024

(54) SYSTEM FOR ETCHING WITH A PLASMA

(71) Applicant: Adaptive Plasma Technology Corp., Icheon-si (KR)

(72) Inventors: Woo Hyung CHOI, Seongnam-si (KR); Sang Woo LEE, Suwon-si (KR)

(21) Appl. No.: 17/947,850

(22) Filed: Sep. 19, 2022

(51) Int. Cl. H01J 37/32

(52) U.S. Cl. CPC H01J 37/32082; H01J 37/32568; H01J 37/32642; H01J 37/32715; H01J 2237/2007; H01J 2237/334

(57) ABSTRACT

Provided is a system for etching with a plasma present invention relates to a system. A system for etching with plasma comprises a source power module 11 for applying a RF power to an upper electrode 15; a bias power module 12 for applying a RF power to a lower electrode; and a bias DC power module 13 for applying a bias DC power to a wafer 18.

### BACKGROUND OF THE INVENTION

### 1. Field of the Invention

The present invention relates to a system for etching with a plasma, in particular the system for enhancing an etching efficiency by applying a direct current.

### 2. Description of the Related Art

An etching processing of semiconductor manufacturing processes may be performed properly in a chemical etching method or a physical etching method according to a required layer quality. In general, the physical and chemical etching processing may be used together, but the etching process using a physical ion bombardment may have an advantage over the chemical etching process for etching a hard layer such as an oxide layer. It is necessary for a linear moving property to be excellent and for an energy level to be high in case of etching the hard layer deeply in course of the ion bombardment etching process. A capacitive coupled plasma (CCP) method or an inductive coupled plasma (ICP) method generating a plasma by applying a high frequency wave may be applied for the physical etching process. An etching apparatus for etching the hard layer such as the oxide layer may have CCP structure in the semiconductor manufacturing process. In such a CCP structure, a high density plasma may be generated in a manner that a high radio frequency power is applied at an upper electrode and a low radio frequency power is applied at a lower electrode. When the plasma is generated by the upper and lower electrodes, a self dc bias voltage may be generated on a surface of a wafer and the etching processing may be performed by controlling the plasma and the bias voltage. PCT publication number WO 2005/059960 discloses a technique to control a plasma density for providing a uniform wafer processing in course of etching a wafer layer or of forming a layer on the wafer. And PCT publication number WO 2020/035479 discloses a plasma etching apparatus and a process for etching a semiconductor substrate with the plasma. The self dc bias voltage generated on the wafer by the RF power has a lower energy efficiency. And therefore, as the semiconductor process advances to a micro pattern structure to etch a smaller size more deeply, it is difficult for the self dc bias voltage to be applied to such a process. For solving this problem, a larger RF power may be used, but an arcing phenomenon occurs easily owing to such a larger RF power, and it is difficult to obtain a durability. And furthermore, the plasma density may become non-uniform partially. And therefore, a method has to be developed to solve the above-mentioned problems.

The present invention is to solve to the problems and has a purpose mentioned below.

### Purpose of the Invention

An object of the present invention is to provide with a plasma etching system for enhancing an etching process efficiency by applying a dc power directly to a wafer in course of etching with plasma.

### SUMMARY OF THE INVENTION

In one embodiment of the present invention, a system for etching with plasma comprises a source power module for applying a RF power to an upper electrode; a bias power module for applying a RF power to a lower electrode; and a bias DC power module for applying a bias DC power to a wafer.

In other embodiment of the present invention, a pulse power is applied by the bias DC power module.

In another embodiment of the present invention, the bias DC power is supplied by a plurality of DC electrode pins arranged on an electrostatic chuck.

In still another embodiment of the present invention, each DC electrode pin is protruded in a way of penetrating an upper surface of the electrostatic chuck along a vertical direction.

In still another embodiment of the present invention, each DC electrode pin is capable of moving elastically in an upward and downward direction.

In still another embodiment of the present invention, a frequency of the DC pulse power becomes a 1 Hz to 1,000 kHz.

In still another embodiment of the present invention, a DC power is applied to an edge ring by the bias DC power module.

In still another embodiment of the present invention, the system comprises a plurality of DC electrode pins protruded onto an upper surface of an electrostatic chuck and arranged along a circumference.

In still another embodiment of the present invention, the plurality of the DC electrode pins are insulated each other, and the number of the pins becomes 2 to 1,000.

### BRIEF DESCRIPTION OF THE DRAWINGS

FIG. 1 shows an exemplary embodiment of an etching system with plasma according to the present invention.

FIG. 2 shows an exemplary embodiment of an electrostatic chuck for the plasma etching system according to the present invention.

FIG. 3 shows another exemplary embodiment of the etching system according to the present invention.

FIG. 4 shows an exemplary embodiment of a method for performing an etching process using the plasma etching system according to the present invention.

### DETAILED DESCRIPTION OF EXEMPLARY EMBODIMENTS

Exemplary embodiments of the present invention will be described herein below with reference to the accompanying drawings.

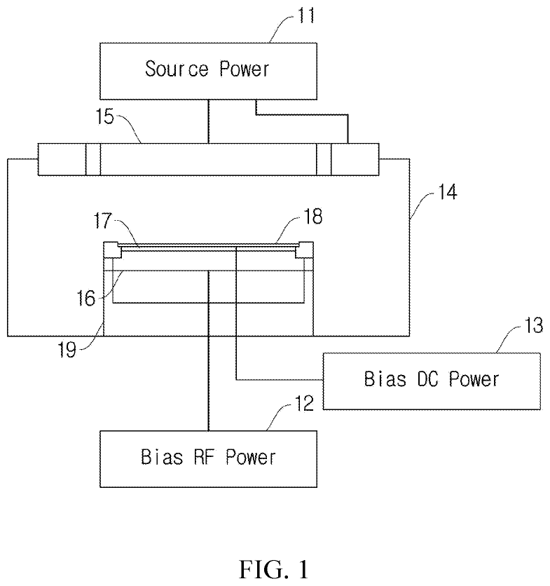

FIG. 1 shows an exemplary embodiment of an etching system with plasma according to the present invention.

Referring to FIG. 1, a system for etching with plasma comprises a source power module 11 for applying a RF power to an upper electrode 15; a bias power module 12 for applying a RF power to a lower electrode; and a bias DC power module 13 for applying a bias DC power to a wafer 18.

A plasma may be generated within a processing chamber 14, and the plasma may be generated in a way of capacitive coupled plasma (CCP) method in which the plasma is generated by an upper electrode 15 and a lower electrode facing each other. A wafer 17 may be secured on an upper surface of an electrostatic chuck placed within the processing chamber 14, and an etching process may be performed with the generated plasma. The upper electrode 15 with a circular flat shape may be arranged at an upper part of the processing chamber 14, the electrostatic chuck may be placed at a lower part of the processing chamber 14 to face the upper electrode 15, and a lower electrode may be placed at the electrostatic chuck. The electrostatic chuck may be formed on a body 19, and comprises a base block 16 made from a metal material such as an aluminum; and an insulating layer 17 formed on the base block 16 made from a ceramic material. The body 19 may have various structure to support the electrostatic chuck, and the base block 16 may have a circular flat shape in general. And also, the insulating layer 17 may become a circular flat shape coupled to an upper part of the base block 16, or the insulating layer 17 may have a shape to enclose the upper surface and an edge surface of the base block 16. The insulating layer 17 may be coupled to the base block 16 by an adhesive layer, and the lower electrode may be formed at a lower part of the insulating layer 17, for example. If the wafer 18 is secured on the upper surface of the electrostatic chuck, the plasma can be generated to perform an etching process. A RF power may be applied to the upper electrode 15 by the source power module 11 for generating the plasma. The RF power may have a 20 MHz to 150 MHz frequency and 1 to 20 kW power. When the RF power is applied to the upper electrode 15, the bias RF power may be applied to the lower electrode placed under the insulating layer 17 by the bias RF power module 12. The bias RF power may have a 100 kHz to 20 MHz frequency and a 10 to 20 kw power. If the RF power and the bias RF power are applied to the upper electrode 15 and the lower electrode, respectively, then the plasma can be generated to perform the etching process. But if the etching process is performed in the above-mentioned way, then an ion bombardment effect to the surface of the wafer may become weak. Thereby, the process may have a disadvantage that it is difficult for a solid layer to be etched in deep thickness.

According to one embodiment of the present invention, a direct current can be applied to the wafer 18 by the bias DC power module 13 for inducing the ion bombardment on the surface of the wafer. The bias DC power module 13 may have a function to apply a DC voltage to the wafer, or between the wafer and the upper surface of the electrostatic chuck or the plasma.

The bias DC power module 13 can apply a pulse type of a power, for example, the bias DC power module 13 can apply DC power with a 5 to 20 kW power and a 1 Hz to 20 kHz frequency for generating −5 kV to −20 kV voltage. And the bias DC power module 13 may apply a DC pulse power with a 1 to 99% duty cycle for enhancing the ion bombardment effect. As mentioned above, the DC electrode may be placed at the electrostatic chuck for the bias DC power. The DC electrode may be made as various structures, and the electrostatic chuck with the DC electrode is explained below.

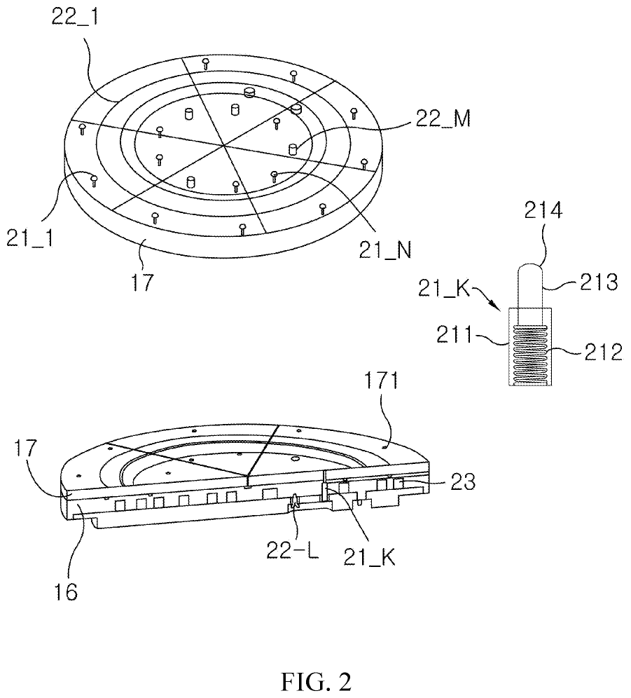

FIG. 2 shows an exemplary embodiment of an electrostatic chuck for the plasma etching system according to the present invention.

Referring to FIG. 2, the lower electrode may be formed at the electrostatic chuck (ESC) within the processing chamber or the etching chamber, thereby, ESC may comprise the insulating layer 17 with a ceramic plate shape forming an upper plane where the wafer is secured; and the base block 16 coupled to the lower surface of the insulating layer 17 by the adhesive layer. The insulating layer 17 may have a circular flat shape in general, and DC electrode(s) for fixing the wafer on the ESC may be placed within the insulating layer 17. The base block 16 may have a shape of a drum in general, may be made from a heat conducting material such as an aluminum, and may comprise at least one cooling flowing line 23. In such an electrostatic structure, the RF power for the lower electrode may be applied to the base block 16 corresponding the lower part of the electrostatic chuck to become energy-coupling with the plasma ignited by the source RF power applied to the upper electrode of the etching chamber for performing the etching process. In such process, the DC pulse power may be applied in various ways, for example, the DC pulse power may be applied to the base block 16 corresponding to the lower part of the electrostatic chuck together with the RF power. In such DC pulse power applying case, the RF power can be transferred through a capacitor, but it may have a disadvantage that it is difficult for the DC power to transfer an energy through a capacitor formed by the base block 16, the insulating layer 17 and the wafer to the surface of the wafer and the plasma, or that the transferring rate may be very small. Therefore, a method for enhancing the energy transferring rate of the DC power transferred to the wafer, and thereby for enhancing the etching efficiency has to be developed.

In according to one embodiment of the present invention, the bias DC electrode for transferring the DC pulse power may be placed at the electrostatic chuck, and the DC bias power can be applied to the wafer or the plasma by the bias DC electrode.

As shown in FIG. 2, the bias DC electrode may comprise at least two DC electrode pin 21_1 to 21_N. The plurality of DC electrode pins 21_1 to 21_N may be arranged uniformly on the upper surface of the electrostatic chuck with a circular flat shape. For example, the DC electrode pins 21_1 to 21_N may be arranged along circumferences corresponding to different radii, and each DC electrode pin 21_1 to 21_N may be separated each other with the same circumferential distance. The number of the pins 21_1 to 21_N may be 2 to 1,000, preferably 5 to 100 and more preferably 5 to 30, but not limited to.

Each DC electrode 21_1 to 21_N may penetrate the base block 16 and the insulating layer 17 to protrude over the upper surface of the electrostatic chuck or the upper surface of the insulating layer 17 in a vertical direction. And also, each DC electrode pin 21_1 to 21_N may move elastically in a upward and downward direction. Each DC electrode pin 21_K may comprise an elastic unit 212 placed within a fixing path 211; and a contacting pin 213 coupled to the elastic unit 212 and moving upward and downward. The elastic unit 212 may become a coil spring, a flat spring, an elastic pad or the like. An end part of the contacting pin 213 may comprise a curved portion 214 and selectively the curved portion 214 may have an elasticity. At least the contacting pin 213 may be a conducting material, and for example, the contacting pin 213 may be made from a metal material and may be coated with a platinum or the gold. At least a portion of the contacting pin 213 may protrude over the insulating layer 17, for example, in a length of 0.5 to 3 mm. And if a pressure may be applied on the contacting pin 213 by the wafer, the contacting pin 213 may be moved in a downward direction. When the wafer is located and secured, the plurality of the DC electrode pins 21_1 to 21_N may contact the lower part of the wafer. The pulse type of the direct current supplied by the DC power module may be applied to the wafer by the DC electrode pins 21_1 to 21_N, and thereby the ion bombardment effect may be improved. The DC power may be applied to the wafer or the plasma by the plurality of DC electrode pins 21_1 to 21_N having various shapes, but not limited to. And also, the DC power supplying means may have various shapes such as the above-mentioned pins, but not limited to.

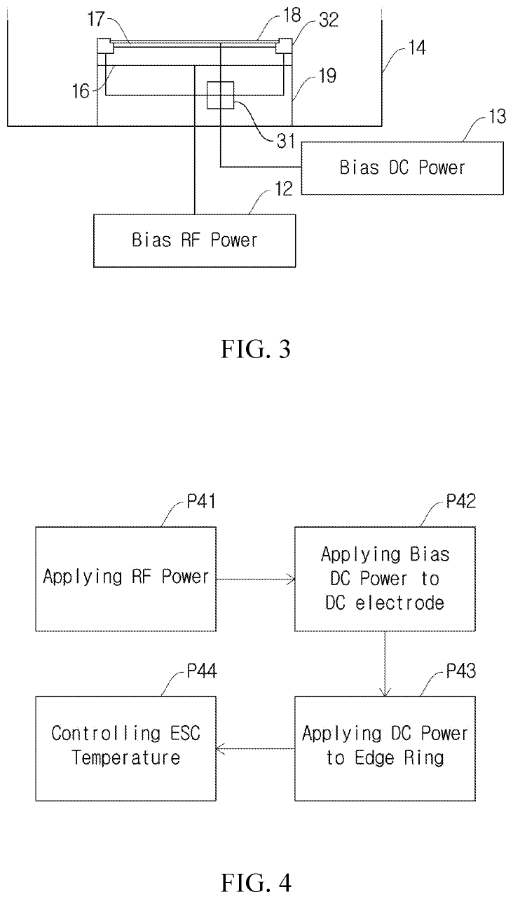

FIG. 3 shows other exemplary embodiment of the etching system according to the present invention.

Referring to FIG. 3, it is necessary for the plasma to be distributed uniformly on base of the surface of the wafer in course of the etching, and also, the ion bombardment effect may be required to be generated uniformly on the whole surface of the wafer. For example, the density of the plasma on the center part of the wafer and on the peripheral part of the wafer has to be uniform, and also, the ion bombardment effect has to occur uniformly on the center part and the peripheral part together. Thereby, the uniformity of the process result can be obtained and the problem of pattern profile tilt at an edge part can be avoid. For this, the DC pulse power may be applied at an edge ring. A wire pattern for supplying the power to the plurality of the DC electrode pins by the bias DC power module 13 may be formed, and at the same time the DC pulse power may be also applied to the edge ring 32. In particular, a distributing circuit 31 may be formed at a power supplying path of the bias DC power module 13 to control the DC pulse power supplied to the edge ring 32.

The edge ring 32 may be made of a Si or SiC material, and a bias power applying electrode similar to the DC electrode pins may be formed at a position where the edge ring 32 is located. The DC pulse power supplied to the edge ring 32 may have an electrical property similar to the DC pulse power supplied to the wafer, but, if necessary, a DC pulse power with a different electrical property can be applied. A DC pulse power with various properties on base of the plasma density or an etching condition can be applied to the edge ring, but not limited to.

FIG. 4 shows an exemplary embodiment of a method for performing an etching process using the plasma etching system according to the present invention.

Referring to FIG. 4, an etch process for a wafer comprises arranging an DC electrode for applying a bias DC power to an electrostatic chuck, and generating a plasma by an RF power to an upper electrode and a lower electrode after securing a wafer at the electrostatic chuck P41; applying a bias DC power to the DC electrode contacting the wafer when the plasma is generated P42; applying a bias DC power to the DC electrode arranged at a position where the edge ring is located P43; and controlling a temperature of the electrostatic chuck depending on the applied DC power P44.

The bias DC electrode arranged at the electrostatic chuck comprising a portion where the edge ring is located may have a DC electrode pin structure as mentioned above, but not limited to. The DC electrode pins may be arranged uniformly on base of the position where the wafer and the edge ring are secured P41. The frequency of the RF power applied to the upper electrode may become 27 MHz, 40 MHz or 100 MHz, but not limited to. And the frequency of the RF power may become 13.56 MHz, 2 MHz or 400 kHz, but not limited to. If the RF powers are applied to the upper electrode and the lower electrode, then a plasma may be generated within an etching chamber and the etching process can proceed. In such a course, the bias DC power is applied to the DC electrode pins contacting the wafer for performing the etching process as a required level, for example, and the bias DC power may become a DC pulse power. The DC pulse power may have a frequency range of 1 Hz to 1,000 Hz and may have a pulse power with 99% duty cycle, but not limited to. The DC pulse power applied to the edge ring may be a power similar to or the same as the DC pulse power applied to the wafer, but it depends on the plasma density condition. The plasma state within the etching chamber may be detected, and the property of the DC pulse power applied to the edge ring may be controlled on base of the detected plasma density. The method for applying the DC pulse power to the wafer and/or the edge ring may be selected in various way, but not limited to.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A system for etching with plasma, comprising:
a source power module 11 for applying a RF power to an upper electrode 15;
a bias power module 12 for applying a RF power to a lower electrode; and
a bias DC power module 13 for applying a bias DC power to a wafer 18.

2. The system according to claim 1, wherein a pulse power is applied by the bias DC power module 13.

3. The system according to claim 1, wherein the bias DC power is supplied by a plurality of DC electrode pins 21_1 to 21_N arranged on an electrostatic chuck.

4. The system according to claim 3, wherein each DC electrode pin 21_1 to 21_N is protruded in a way of penetrating an upper surface of the electrostatic chuck along a vertical direction.

5. The system according to claim 3, wherein each DC electrode pin 21_1 to 21_N is capable of moving elastically in an upward and downward direction.

6. The system according to claim 2, wherein a frequency of the DC pulse power becomes a 1 Hz to 1,000 kHz.

7. The system according to claim 1, wherein a DC power is applied to an edge ring by the bias DC power module 13.

8. The system according to claim 1, wherein the system comprises a plurality of DC electrode pins 21_1 to 21_1 protruded onto an upper surface of an electrostatic chuck and arranged along a circumference.

9. The system according to claim 8, wherein the plurality of DC electrode pins 21_1 to 21_N are insulated each other, and the number of the pins becomes 2 to 1,000.
